(19) United States
(12) Patent Application Publication
(10) Pub. No.: US 2008/0197404 A1
(43) Pub. Date: Aug. 21, 2008

(54) Method of fabricating semiconductor memory device and semiconductor memory device

(75) Inventor: Koji Takaya, Tokyo (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 12/003,313

(22) Filed: Dec. 21, 2007

(30) Foreign Application Priority Data
Feb. 20, 2007 (JP) 2007-039530

(51) Int. Cl. H01L 29/792; H01L 21/336

(52) U.S. Cl. 257/324; 438/270; 257/E29.262; 257/E21.41

(57) ABSTRACT

A semiconductor memory device is fabricated by: forming a device isolation region in a recessed portion of a semiconductor substrate having an irregularly-shaped portion; forming a gate electrode wiring trench in a direction orthogonal to a longitudinal direction of an active region which is a projecting portion of the semiconductor substrate having the irregularly-shaped portion in the device isolation region; forming a gate electrode material layer so as to fill the gate electrode wiring trench; forming a gate electrode by patterning the layer formed of the gate electrode material; forming an active region by etching the device isolation region; forming a charge storage layer on at least one side surface of the gate electrode, the surface being adjacent to the projecting portion of the semiconductor substrate having the irregularly-shaped portion; and forming a side wall on at least a part of the charge storage layer.

### CROSS-REFERENCE TO RELATED APPLICATION

This application claims priority under 35 USC 119 from Japanese Patent Application No. 2007-039530, the disclosure of which is incorporated by reference herein.

### BACKGROUND OF THE INVENTION

1. Field of the Invention

The present invention relates to a method of fabricating a semiconductor device and a semiconductor memory device, particularly to a method of fabricating a semiconductor memory device usable to, for example, a semiconductor non-volatile memory, and a semiconductor memory device.

2. Description of Related Art

Currently, a semiconductor non-volatile memory is used as a memory for low power appliances such as a cellular telephone, because the memory does not require electric power to hold stored information.

Among them, such a semiconductor non-volatile memory is proposed that a charge storage layer is provided so as to sandwich a gate electrode (for example, see JP-A-2006-24680). The semiconductor non-volatile memory like this functions as a memory by accumulating electrons in the charge storage layer. In other words, the memory has a function that the current amount of the memory (transistor) is changed depending on whether electrons exist in the charge storage layer to read data of “0” and “1”.

On the other hand, in recent years, the scale of devices for use in the semiconductor memory device including the semiconductor non-volatile memory is increasingly smaller. A fin field effect transistor is proposed that is one kind of three dimensional structure MIS semiconductor memory devices (for example, see JP-A-2003-163356, JP-A-2004-214413, and U.S. Pat. No. 6,413,802). As shown in FIG. 11, the structure of a semiconductor memory device 200 is also proposed in which a charge storage layer 96 formed of three layers, an oxide film 90, a nitride film 92 and an oxide film 94, is provided on the bottom part of a gate electrode 88 (for example, see JP-A-2004-172559).

However, the scale of the semiconductor non-volatile memory having the charge storage layer described above is smaller and smaller as well as the gate dimensions are reduced and the width of the gate electrode is finer. Then, the channel length is shortened to cause short channel effect, and to cause leakage current flow between the source region and the drain region even though the gate is closed (hereinafter, properly referred to as “punch through”).

In addition, the gate electrode is generally formed in order of depositing a gate electrode material and patterning a gate electrode. However, the scale-down of the gate dimensions causes an etched gate electrode material to remain between gate electrodes in forming the gate electrodes, which may result in a short circuit between the adjacent gate electrodes, and thus more improvement is demanded.

### SUMMARY OF THE INVENTION

The invention has been made in view of the problems, and an object is to achieve the following purpose.

In other words, an object of the invention is to provide a semiconductor memory device with excellent reliability and a method of fabricating the same.

The inventor diligently investigated to find that the problems can be solved by using a method of fabricating a semiconductor device described below and achieved the object.

In other words, a method of fabricating a semiconductor memory device according to a first aspect of the invention is a method of fabricating a semiconductor memory device having a gate electrode and a charge storage layer, the method including: forming a device isolation region in a recessed portion of a semiconductor substrate having an irregularly-shaped portion; forming a gate electrode wiring trench in the device isolation region in a direction orthogonal to a longitudinal direction of a projecting portion of the semiconductor substrate having the irregularly-shaped portion; forming a layer formed of a gate electrode material so as to fill in the gate electrode wiring trench; forming a gate electrode by patterning the layer formed of the gate electrode material; forming an active region by etching the device isolation region; forming a charge storage layer on at least one side surface of the gate electrode, the surface being adjacent to the projecting portion of the semiconductor substrate having the irregularly-shaped portion; and forming a side wall on at least a part of the charge storage layer.

Further, in a second aspect of the invention, the forming of the charge storage layer is performed after the forming of the gate electrode in the first aspect.

In accordance with the method of fabricating a semiconductor memory device according to the first and second aspects of the invention, since the device isolation region is etched in order to expose the portion buried in the gate electrode wiring trench of the gate electrode, there are no remains of the etched gate electrode material between the gate electrodes, and thus a factor of a short circuit between the gate electrodes can be suppressed.

In addition, the charge storage layer forming process is performed after the gate electrode forming process, and then the charge storage layer is formed on the side wall part of the gate electrode, which can increase the capacity of the charge storage layer. Therefore, the factor of a short circuit between the gate electrodes can be suppressed as well as a reduction in the scale of the semiconductor memory device can be coped with no reduction in the amount of electric charges to store.

In addition, a third aspect of the invention is a semiconductor memory device including: a semiconductor substrate having an irregularly-shaped portion; a gate electrode that covers at least two side surfaces of an active region formed of a projecting portion of the semiconductor substrate having the irregularly-shaped portion; a charge storage layer that covers at least one side surface of the gate electrode, the surface being adjacent to the projecting portion of the semiconductor substrate having the irregularly-shaped portion; a side wall that is formed so as to cover at least a part of the charge storage layer; a channel region that is formed in the active region in an area covered by the gate electrode in the active region; a source region and a drain region that are formed in the active region so as to sandwich the channel region; and an extension region that is formed in the active region at least one of an area between the channel region and the source region and an area between the channel region and the drain region.

In accordance with the semiconductor device according to the third aspect of the invention, the side wall is formed to optimize the distance between the source region and the drain region for suppressing punch through.

According to the invention, a semiconductor memory device with excellent reliability and a method of fabricating the same can be provided.

### BRIEF DESCRIPTION OF THE DRAWINGS

Preferred exemplary embodiments of the present invention will be described in detail based on the following figures, wherein:

FIG. 1 shows a perspective cross section depicting a device isolation region forming process in which a device isolation region is formed in a recessed portion of a semiconductor substrate having an irregularly-shaped portion in a method of fabricating a semiconductor device according to the embodiment of the invention;

FIG. 2 shows a perspective cross section seen from the device isolation region side, depicting a gate electrode wiring trench forming process in which in the device isolation region, a gate electrode wiring trench is provided in the direction orthogonal to the longitudinal direction of a projecting portion of the semiconductor substrate having the irregularly-shaped portion in the method of fabricating the semiconductor device according to the embodiment of the invention;

FIG. 3A shows a perspective cross section seen from the device isolation region side, depicting a gate electrode material layer forming process in which a layer formed of a gate electrode material is formed so as to blurry the gate electrode wiring trench in the method of fabricating the semiconductor device according to the embodiment of the invention;

FIG. 3B shows a perspective cross section seen from the gate electrode wiring trench side;

FIG. 4A shows a perspective cross section seen from the device isolation region side, depicting a gate electrode forming process in which a layer formed of the gate electrode material is patterned to form a gate electrode in the method of fabricating the semiconductor device according to the embodiment of the invention;

FIG. 4B shows a perspective cross section seen from the gate electrode wiring trench side;

FIG. 5A shows a perspective cross section seen from the device isolation region side, depicting an active region forming process in which the device isolation region is etched to form an active region in the method of fabricating the semiconductor device according to the embodiment of the invention;

FIG. 5B shows a perspective cross section seen from the gate electrode wiring trench side;

FIG. 6 shows a perspective cross section seen from the device isolation region side, depicting a charge storage layer forming process in which a charge storage layer is formed on at least one of the side wall parts of the gate electrode in the method of fabricating the semiconductor device according to the embodiment of the invention;

FIG. 7A shows a perspective cross section seen from the device isolation region side, depicting a side wall forming process in which a side wall is formed on at least a part of the charge storage layer in the method of fabricating the semiconductor device according to the embodiment of the invention;

FIG. 7B shows a perspective cross section seen from the gate electrode wiring trench side;

FIG. 8A shows a diagram seen from the top of a semiconductor memory device fabricated by the fabricating method according to the invention;

FIG. 8B shows a diagram seen from the top of a semiconductor memory device fabricated by a fabrication process before;

FIG. 9 shows a perspective view depicting a semiconductor device according to the embodiment of the invention;

FIG. 10A shows a cross section in line A-A shown in FIG. 9;

FIG. 10B shows a cross section in line B-B; and

FIG. 11 shows a perspective view depicting a semiconductor device before.

### DETAILED DESCRIPTION OF THE INVENTION

Hereinafter, the best mode which can implement a method of fabricating a semiconductor memory device according to the invention will be described with reference to the drawings. Moreover, the overlapping descriptions are sometimes omitted.

### <A Method of Fabricating a Semiconductor Memory Device>

A method of fabricating a semiconductor memory device having a gate electrode and a charge storage layer, the method includes: forming a device isolation region in a recessed portion of a semiconductor substrate having an irregularly-shaped portion; forming a gate electrode wiring trench in a direction orthogonal to a longitudinal direction of a projecting portion of the semiconductor substrate having the irregularly-shaped portion in the device isolation region; forming a layer formed of a gate electrode material so as to fill in the gate electrode wiring trench; forming a gate electrode by patterning the layer formed of the gate electrode material; forming an active region by etching the device isolation region; and forming a charge storage layer on at least one of side surfaces of the gate electrode, the surface being adjacent to the projecting portion of the semiconductor substrate having the irregularly-shaped portion; and forming a side wall on at least a part of the charge storage layer.

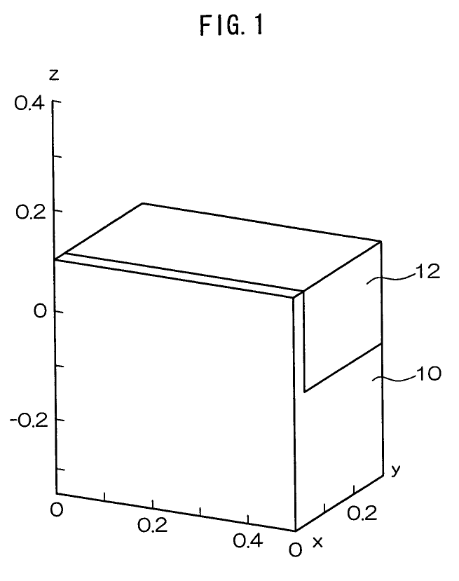

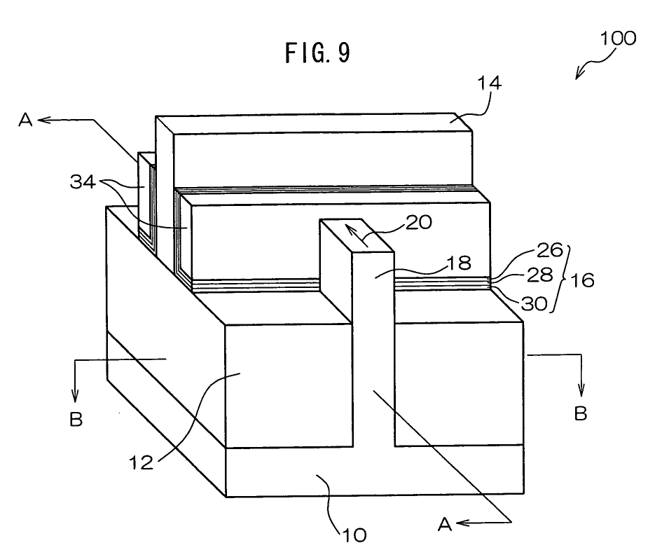

Hereinafter, the descriptions of the individual processes will be described with reference to FIGS. 1 to 7B seen from a cross section line A-A of a semiconductor device 100 according to the invention shown in FIG. 9.

[A Device Isolation Region Forming Process in which a Device Isolation Region is Formed in a Recessed Portion of a Semiconductor Substrate Having an Irregularly-Shaped Portion]

As shown in FIG. 1, a method of fabricating a semiconductor memory device according to the invention includes a device isolation region forming process in which a device isolation region 12 is formed in a recessed portion of a semiconductor substrate 10 having an irregularly-shaped portion.

### [The Semiconductor Substrate Having the Irregularly-Shaped Portion]

The semiconductor substrate 10 having the irregularly-shaped portion according to the invention has a projecting portion on which an active region 18, described later, is formed. In addition, in a recessed portion, a device isolation region 12, described later, is formed. Moreover, prior to forming the device isolation region 12, described later, a gate insulating film (not shown) is formed in advance on the front surface of the projecting portion of the semiconductor substrate 10 having the irregularly-shaped portion.

For the semiconductor substrate 10 having the irregularly-shaped portion, an SOI substrate (a substrate having a structure in which SiO₂ is inserted between a Si substrate and a surface Si layer), or a Si substrate can be used.

### [Device Isolation Region]

In this process, the device isolation region 12 according to the invention is formed in which the recessed portion is buried by a publicly known method to deposit the region to the same height at least as the top of the active region 18, described later.

The device isolation region 12 is not restricted particularly as long as those having insulating properties. STI (Shallow trench isolation) (SiO₂ buried shallow trench isolation) may be used.

[A Gate Electrode Wiring Trench Forming Process in which a Gate Electrode Wiring Trench is Provided in the Direction Orthogonal to the Longitudinal Direction of the Projecting Portion of the Semiconductor Substrate Having the Irregularly-Shaped Portion in the Device Isolation Region]

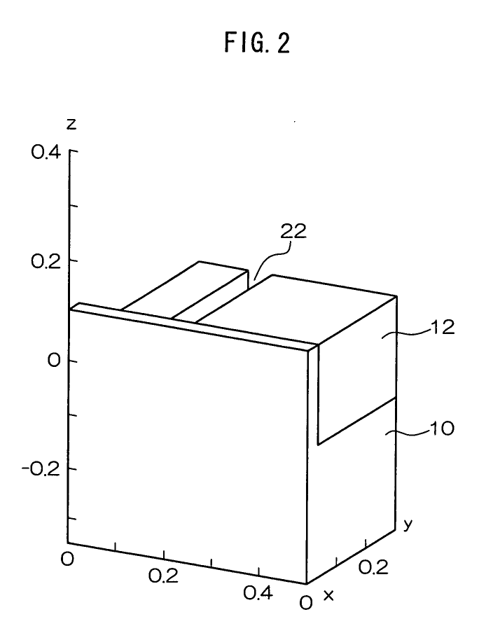

As shown in FIG. 2, the method of fabricating the semiconductor memory device according to the invention includes a gate electrode wiring trench forming process in which a gate electrode wiring trench 22 is provided in the direction orthogonal to the longitudinal direction of the projecting portion of the semiconductor substrate 10 having the irregularly-shaped portion in the device isolation region 12.

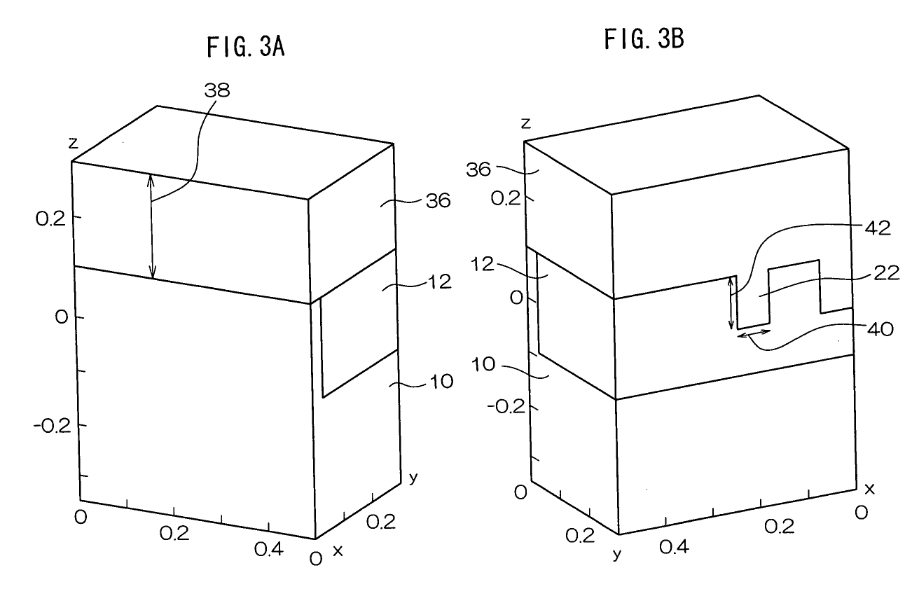

The gate electrode wiring trench 22 is used to fill in a gate electrode 14, described later, which can be freely set depending on the specifications of a semiconductor memory device. The depth and width of the gate electrode wiring trench 22 will be described in detail with reference to FIGS. 3A and 3B.

The gate electrode wiring trench 22 is formed by a well-known technique such as photo-etching.

[A Gate Electrode Material Layer Forming Process in which a Layer Formed of a Gate Electrode Material is Formed so as to Fill in the Gate Electrode Wiring Trench]

As shown in FIGS. 3A and 3B, the method of fabricating the semiconductor memory device according to the invention includes a gate electrode material layer forming process in which a layer 36 formed of a gate electrode material is formed so as to fill in the gate electrode wiring trench 22. Moreover, FIG. 3A shows a perspective cross section seen from the cross section of the projecting portion of the semiconductor substrate 10 having the irregularly-shaped portion, and FIG. 3B shows a perspective cross section seen from the gate electrode wiring trench 22 side.

A layer 36 formed of the gate electrode material is buried in the gate electrode wiring trench 22 so as to facilitate patterning of the gate electrode 14, described later, and so as not to cause the remains of the etched material of the gate electrode, described later.

Preferably, a film thickness 38 of the layer 36 formed of the gate electrode material is a half of a width 40 of the gate electrode wiring trench 22 or greater from the viewpoint of filling the gate electrode wiring trench 22 with no clearance. Here, the film thickness 38 of the layer 36 formed of the gate electrode material is the height from the top of the projecting portion of the semiconductor device 10 having the irregularly-shaped portion to the top of the layer 36 formed of the gate electrode material.

Preferably, a depth 42 of the gate electrode wiring trench 22 is smaller than the sum of the height of the gate electrode 14, described later, and a mask material (not shown) provided to form the gate electrode 14.

For example, the layer 36 formed of the gate electrode material can be formed by CVD (Chemical Vapor Deposition).

In the method of fabricating the semiconductor memory device according to the invention, in order to pattern the gate electrode 14, described later, the mask material (not shown) is formed on the front surface of the layer 36 formed of the gate electrode material. Here, preferably, the sum of the film thickness 38 of the layer 36 formed of the gate electrode material and the film thickness of the mask material is greater than the height 46 of the active region 18, described later, in order to form a side wall 34, described later. In addition, preferably, also in the case in which the mask material is not deposited and only the gate electrode 14 is formed, the film thickness 38 of the layer 36 formed of the gate electrode material is greater than the height 46 of the active region 18, described later.

For the gate insulating material in the invention, well-known materials can be used. For example, oxide films, oxide nitride films and oxide films added with rare earth can be used.

[A Gate Electrode Forming Process in which the Layer Formed of the Gate Electrode Material is Patterned to Form a Gate Electrode]

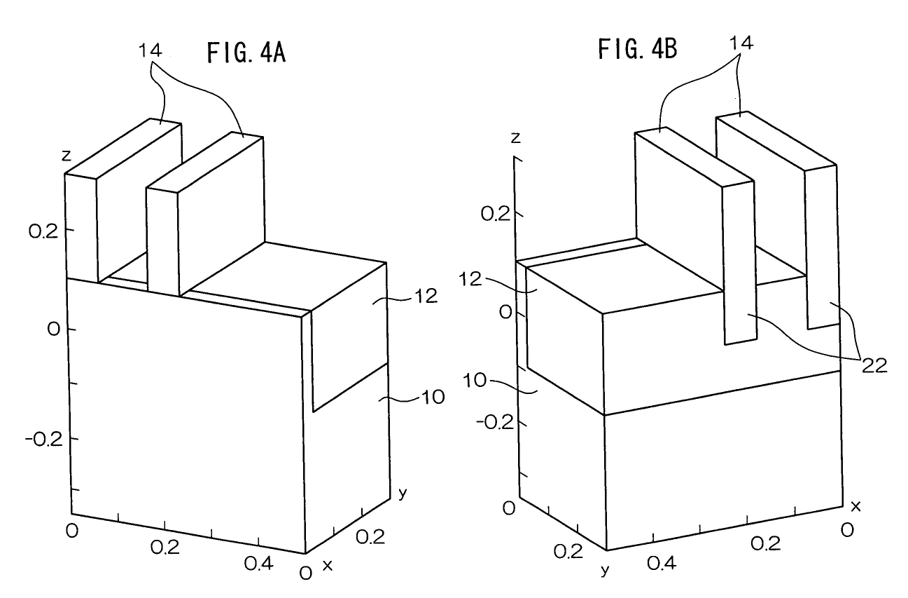

As shown in FIGS. 4A and 4B, the method of fabricating the semiconductor memory device according to the invention includes a gate electrode forming process in which the layer 36 formed of the gate electrode material is patterned to from the gate electrode 14. Moreover, FIG. 4A shows a perspective cross section seen from the cross section of the projecting portion of the semiconductor substrate 10 having the irregularly-shaped portion, and FIG. 4B shows a perspective cross section seen from the gate electrode wiring trench 22 side.

The gate electrode 14 is formed by etching the layer 36 to the front surface of the device isolation region 12 according to well-known photo-etching.

In addition, the width of the gate electrode 14 is the same as the width 40 of the gate electrode wiring trench 22.

[An Active Region Forming Process in which the Device Isolation Region is Etched to Form the Active Region]

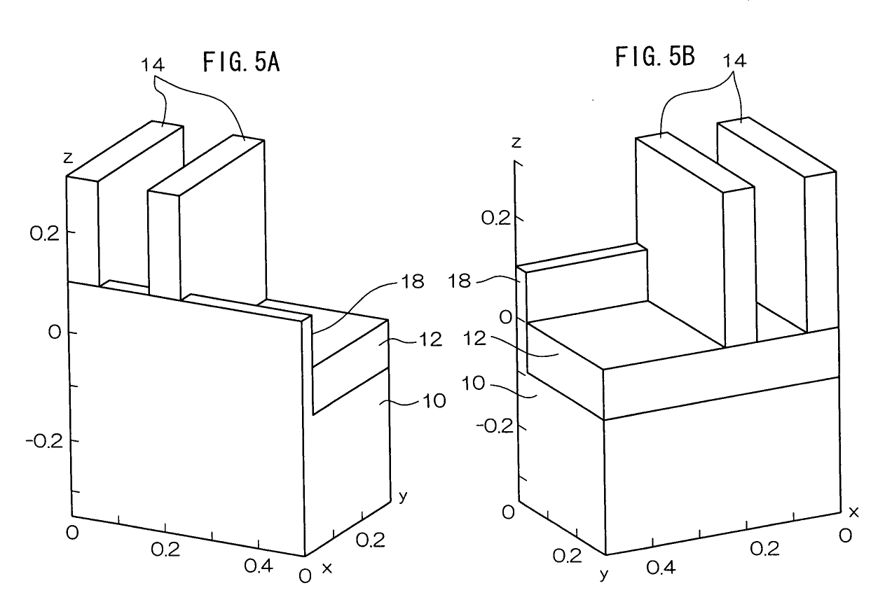

As shown in FIGS. 5A and 5B, the method of fabricating the semiconductor memory device according to the invention includes an active region forming process in which the device isolation region 12 is etched to form the active region 18. Moreover, FIG. 5A shows a perspective cross section seen from the cross section of the projecting portion of the semiconductor substrate 10 having the irregularly-shaped portion, and FIG. 5B shows a perspective cross section depicting the gate electrode wiring trench 22 side.

The device isolation region 12 is etched by photo-etching before, to form the active region 18. The height from the front surface of the device isolation region 12 to the front surface of the active region 18 after etching (hereinafter, properly referred to as “the height of the active region”) can be freely changed depending on the specifications of a semiconductor memory device. However, in view of removing the remains of the etched gate electrode material in forming the gate electrode 14, preferably, the ratio of the height of the active region to the depth of the gate electrode wiring trench is 1 or below, with respect to the depth 42 of the gate electrode wiring trench 22.

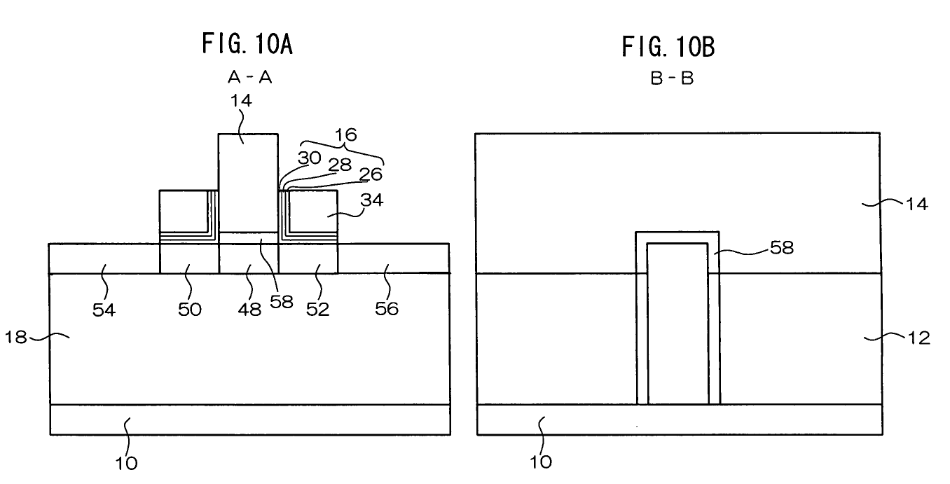

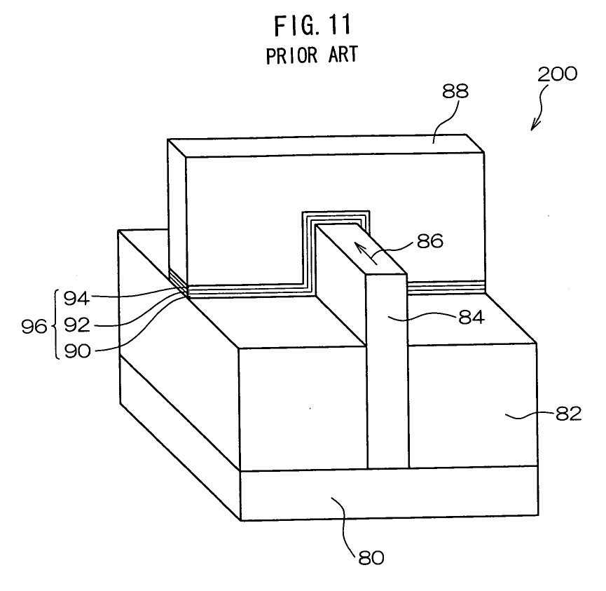

Subsequently, after the device isolation region 12 is etched, in order to suppress punch through due to short channel effect, an impurity is injected into an area not covered with the gate electrode 14 in the device isolation region 12 by a well-known implantation technique, and then extension regions 50 and 52 are formed as shown in FIG. 10A.

For example, for the impurity, P, As, and B can be used.

[A Charge Storage Layer Forming Process in which a Charge Storage Layer is Formed on at Least One of the Side Surfaces of the Gate Electrode and Adjacent to the Projecting Portion of the Semiconductor Substrate Having the Irregularly-Shaped Portion]

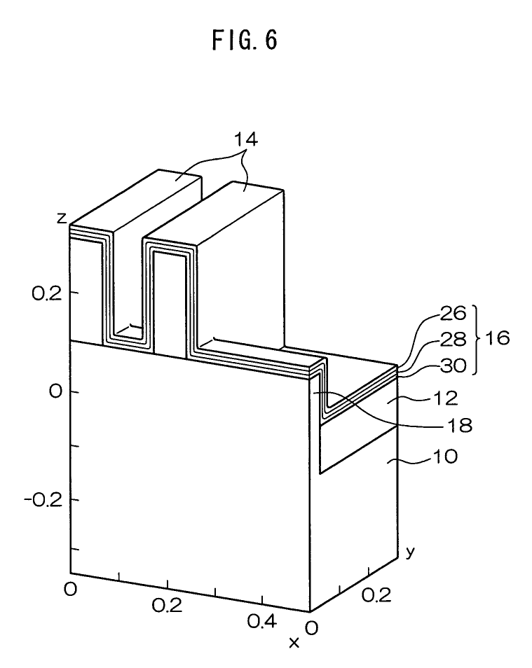

As shown in FIG. 6, the method of fabricating the semiconductor memory device according to the invention includes a charge storage layer forming process in which a charge storage layer 16 that is formed on at least one of the side surfaces of the gate electrode 14, the surface being adjacent to the projecting portion of the semiconductor substrate 10 having the irregularly-shaped portion.

The charge storage layer 16 is formed on the gate electrode 14, the side surface part of the active region 18, the top of the active region 18, and the front surface of the device isolation region 12.

The charge storage layer 16 is configured of a multilayer structure (ONO: Oxide Nitride Oxide) in which first, for example, a bottom oxide film 30 formed of SiO₂ is formed by a well-known technique, a silicon nitride film 28, for example, formed of SiN is formed on the front surface of the bottom oxide film 30, and then a top oxide film 26 formed, for example, of SiO₂ on the front surface of the silicon nitride film 28.

In order to implement the determination of reads of the charge easily, preferably, the film thickness of the charge storage layer 16 is formed to have the bottom oxide film 30 having a film thickness of 0.0065 μm or greater and the top oxide film 26 having a film thickness of 0.0065 μm.

In addition, the bottom oxide film 30 can be formed by a well-known oxidation technique, the silicon nitride film 28 can be formed by CVD, and the top oxide film 26 can be formed by oxidation or CVD.

In addition, preferably, the charge storage layer forming process is performed after the gate electrode 14 is formed. In the semiconductor memory device fabricate by the method of fabricating the semiconductor memory device according to the invention, since the charge storage layer 16 is provided on the surface that is the side surface of the gate electrode 14 and adjacent to the projecting portion of the semiconductor substrate 10 having the irregularly-shaped portion, it is preferable to provide the charge storage layer 16 after the gate electrode 14 is formed in fabrication.

[A Side Wall Forming Process in which a Side Wall is Formed on at Least a Part of the Charge Storage Layer]

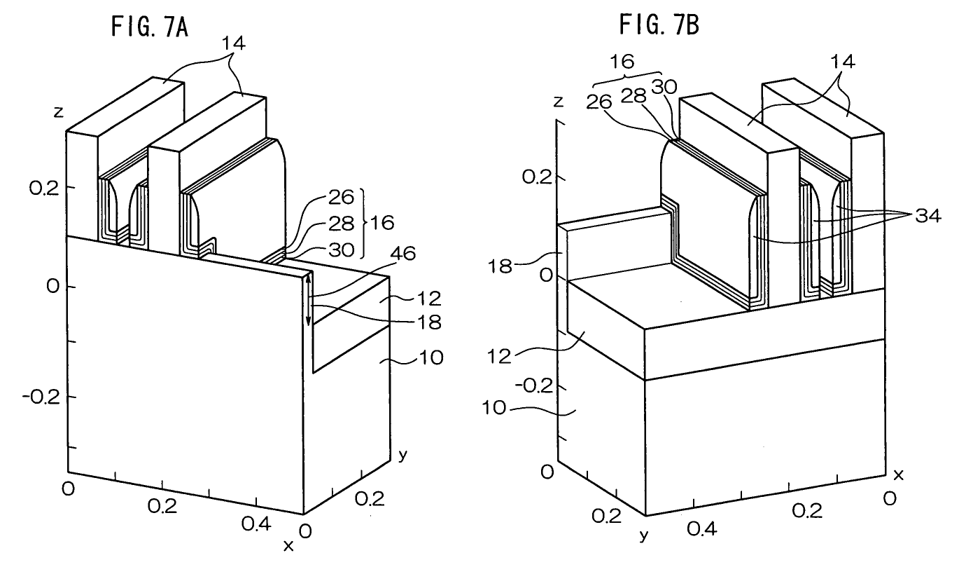

As shown in FIGS. 7A and 7B, the method of fabricating the semiconductor memory device according to the invention includes a side wall forming process in which the side wall 34 is formed on at least a part of the charge storage layer 16. Moreover, FIG. 7A shows a perspective cross section seen from the cross section of the projecting portion of the semiconductor substrate 10 having the irregularly-shaped portion, and FIG. 7B shows a perspective cross section seen from the gate electrode wiring trench 22 side.

The side wall(s) 34 is(are) formed in which first, a nitride film that is a side wall material is deposited, and then the nitride film is etched by anisotropic etching to form the side wall 34. In the invention, since a height 39 that is the sum of the gate electrode 14 on the top of the active region 18 and the mask material (not shown) (hereinafter, properly referred to as “X”) is higher than the height from the front surface of the device isolation area 12 to the top of the active region 18, that is, the height 46 of the active region 18 (hereinafter, properly referred to as “Y”), the side wall 34 is formed only on the surface of the charge storage layer 16. In other words, the height of the side wall 34 from the front surface of the device isolation region 12 is X-Y. Therefore, since the semiconductor memory device according to the invention has the side wall 34, X is greater than Y.

In addition, in etching the side wall 34, the charge storage layer formed on the side wall part and the top part of the active region 18 and the top part of the gate electrode 14 is also etched, and the charge storage layer 16 is formed only on the side wall part of the gate electrode 14.

For example, for the materials of the side wall 34, silicon dioxides, silicon nitrides, and polysilicons can be used.

In the semiconductor memory device fabricated through these processes, no etched material remains between the adjacent gate electrodes 14, and a factor of a short circuit between the gate adjacent electrodes 14 can be suppressed.

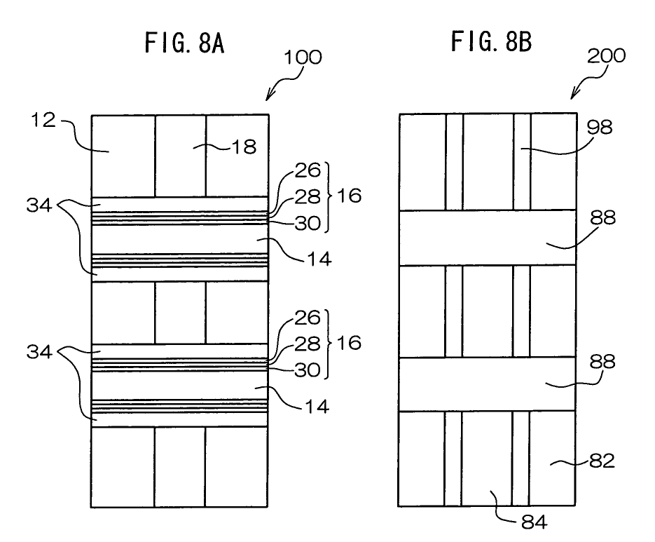

FIG. 8A shows the top of the semiconductor memory device fabricated by the fabricating method according to the invention, and FIG. 8B shows the top of a semiconductor memory device fabricated by a fabrication process before. In the semiconductor memory device 100 fabricated by the fabricating method according to the invention, since there are no remains of the etched gate electrode material between the gate electrodes 14 and no short circuit occurs between the gate electrodes, a highly reliable semiconductor device can be fabricated. In contrast to this, in a semiconductor memory device 200 fabricated by a conventional fabricating method, remains 98 of the etched gate electrode material occur between gate electrodes 88, which cause the gate electrode 88 to be electrically connected to each other. Therefore, there might be failure in the operation, which causes an unreliable device.

### <Semiconductor Memory Device>

FIG. 9 shows the semiconductor memory device according to the invention fabricated by the method of fabricating the semiconductor memory device according to the invention. In addition, FIG. 10A shows a cross section of line A-A shown in FIG. 9, and FIG. 10B shows a cross section of line B-B shown in FIG. 9.

The semiconductor memory device 100 according to the invention includes the semiconductor substrate 10 having the irregularly-shaped portion, the gate electrode 14 that covers at least two side surfaces of the projecting portion of the semiconductor substrate 10 having the irregularly-shaped portion, the charge storage layer 16 that covers at least two side surfaces of the gate electrode 14, and the side wall 34 that is formed to cover at least a part of the charge storage layer 16. Moreover, in the A-A cross section shown in FIG. 10A, the device 100 includes a channel region 48 that is formed in the area covered with the gate electrode 14 in the projecting portion of the semiconductor substrate 10 having the irregularly-shaped portion, a source region 54 and a drain region 56 that are formed in the projecting portion of the semiconductor substrate 10 having the irregularly-shaped portion so as to sandwich the channel region 48, the extension regions 50 and 52 that are formed on at least one of the area between the channel region 48 and the source region 54 and the area between the channel region 48 and the drain region 56 in the projecting portion of the semiconductor substrate 10 having the irregularly-shaped portion, and a gate insulating film 58 that is formed between the channel region 48 and the gate electrode 14.

Hereinafter, a method of recording information on the semiconductor memory device according to the invention will be described.

In the semiconductor device 100 shown in FIG. 9, electric charges are stored (trapped) in the silicon nitride film 28 of the charge storage layer 16, or the stored electric charges are drawn from the silicon nitride film 28 of the charge storage layer 16 (or the electric charges having the opposite pole of the pole of the trapped electric charges are injected), and thus the extension regions 50 and 52 shown in FIG. 10A are modulated depending on the existence of electric charges in the charge storage layer 16, the charge amount and the positive and negative poles, which causes changes in a drain current 20 carried between the source region 54 and the drain region 56 shown in FIG. 10A.

More specifically, in FIGS. 10A and 10B, for example, when electric charges are injected in the charge storage layer 16 to store electric charges, the resistances of the extension regions 50 and 52 are increased to reduce the current. On the other hand, when electric charges are not stored in the charge storage layer 16, the drain current 20 flows sufficiently because the resistance values of the extension regions 50 and 52 are small. The state in which the drain current 20 is reduced and the state in which the current flows are read and associated with the theoretical values “0” and “1” to record or read one bit of information. Since there are two layers of the charge storage layer 16, two bits of information can be recorded and read.

Moreover, electric charges are stored in the charge storage layer 16 on the source region 54 side in which positive voltage is applied to the source region 54 and the gate electrode 14 to allow the drain region 56 to have ground voltage. On the other hand, electric charges are stored in the charge storage layer 16 on the drain region 56 side in which positive voltage is applied to the drain region 56 and the gate electrode 14 to allow the source region 54 to have ground voltage.

As described above, the current value of the drain current 20 flows between the source region 54 and the drain region 56 is read in recording and reading, whereby information is recorded and read. In the embodiment, the active region 18, in which the channel region 48, the source region 54 and the drain region 56 are provided, is formed so as to project, and the drain current 20 flows with a spread in the height direction (the length along the direction orthogonal to the substrate surface) even though the width along in the direction of the substrate surface is reduced because the scale of devices is made smaller. In other words, the channel width is secured in the height direction.

Moreover, although the drain current 20 flows between the source region 54 and the drain region 56 can be controlled by the height of the active region 18, the height of the active region 18 is designed higher to secure the maximum value of the drain current 20 sufficiently. For example, even though the charge amount stored in the charge storage layer 16, described later, is controlled to regulate the drain current 20 step by step, sufficient differences can be provided between the individual steps of the drain current 20, the determination of reads can be implemented easily, and multiple bits of information can be recorded and read in association with three or more theoretical values (for example, “0”, “1”, and “2”).

More specifically, for example, the charge amount of the charge storage layer 16 is controlled in three states: a first state in which electric charges are stored by first charge amount, a second state in which electric charges are stored by a second charge amount lower than the first charge amount, and a third state in which electric charges are not stored. Under this control, the current value of the drain current 20 flows between the source region 54 and the drain region 56 is changed among three states: a first state in which the current is reduced, a second state in which the current is carried more than in the first state, and a third state in which the current is carried more than in the first and second state. These changes in the current value are read, whereby the bit information can be read.

Moreover, in the embodiment, an example of a single device (a semiconductor non-volatile memory cell) is described, but the invention is not restricted thereto, which can be generally adapted to arrayed devices. In the embodiment, since multiple bits of information can be recorded on and read out of a single device (charge storage memory cell), a single device used as a non-volatile memory is arrayed to increase the density of recording information per unit area.

In addition, in the embodiment, the form is described in which two layers of the charge storage layer 16 are provided as shown in FIG. 9, but such a form may be possible in which a single layer of the charge storage layer 16 is provided.

As discussed above, the semiconductor device according to the invention can suppress the factor causing a short circuit between the gate electrodes, which has excellent reliability.

Moreover, it is needless to say that the embodiment should not be interpreted in limited ways, which can be implemented within the scope satisfying the requirements of the invention.

What is claimed is:

1. A method of fabricating a semiconductor memory device having a gate electrode and a charge storage layer, the method comprising:
forming a device isolation region in a recessed portion of a semiconductor substrate having an irregularly-shaped portion;
forming a gate electrode wiring trench in the device isolation region in a direction orthogonal to a longitudinal direction of a projecting portion of the semiconductor substrate having the irregularly-shaped portion;
forming a layer formed of a gate electrode material so as to fill in the gate electrode wiring trench;
forming a gate electrode by patterning the layer formed of the gate electrode material;
forming an active region by etching the device isolation region;
forming a charge storage layer on at least one side surface of the gate electrode, the surface being adjacent to the projecting portion of the semiconductor substrate having the irregularly-shaped portion; and
forming a side wall on at least a part of the charge storage layer.

2. The method of fabricating a semiconductor memory device according to claim 1, wherein the forming of the charge storage layer is performed after the forming of the gate electrode.

3. A semiconductor memory device comprising:
a semiconductor substrate having an irregularly-shaped portion;
a gate electrode that covers at least two side surfaces of an active region formed of a projecting portion of the semiconductor substrate having the irregularly-shaped portion;
a charge storage layer that covers at least one side surface of the gate electrode, the surface being adjacent to the projecting portion of the semiconductor substrate having the irregularly-shaped portion;
a side wall that is formed so as to cover at least a part of the charge storage layer;
a channel region that is formed in the active region in an area covered by the gate electrode in the active region;
a source region and a drain region that are formed in the active region so as to sandwich the channel region; and
an extension region that is formed in the active region at least one of an area between the channel region and the source region and an area between the channel region and the drain region.

4. The semiconductor memory device according to claim 3, wherein a device isolation region is formed in a recessed portion of the irregularly-shaped portion.

5. The semiconductor memory device according to claim 4, wherein the gate electrode is made of a gate electrode material filled in a gate electrode wiring trench formed in the device isolation region.
